(19) United States
(12) Patent Application Publication
(10) Pub. No.: US 2022/0363941 A1
(43) Pub. Date: Nov. 17, 2022

(54) HIGHLY STRETCHABLE SUPERHYDROPHOBIC THIN FILM USING INITIATED CHEMICAL VAPOR DEPOSITION AND METHOD OF PREPARING SAME

(71) Applicant: KOREA ADVANCED INSTITUTE OF SCIENCE AND TECHNOLOGY, Daejeon (KR)

(72) Inventors: Sung Gap IM, Daejeon (KR); Myung Seok Oh, Daejeon (KR); Mingyu Jeon, Daejeon (KR)

(21) Appl. No.: 17/722,471

(22) Filed: Apr. 18, 2022

(30) Foreign Application Priority Data
Apr. 29, 2021 (KR) 10-2021-0055735

(51) Int. Cl. C09D 143/04; C09D 5/00

(52) U.S. Cl. CPC C09D 143/04; C09D 5/00

(57) ABSTRACT

A highly stretchable superhydrophobic thin film using initiated chemical vapor deposition is prepared by a method in which a substrate is coated with a copolymer at a nanometer thickness by allowing a fluorine monomer containing 4 to 6 fluoroalkyl groups and having a glass transition temperature of 5° C. or less to react with a crosslinking monomer on the substrate in the presence of an initiator in an initiated chemical vapor deposition reactor and thus its durability can be secured in foldable and wearable devices.

### CROSS-REFERENCE TO RELATED APPLICATION

This application claims the benefit under 35 USC § 119 of Korean Patent Application No. 10-2021-0055735 filed in the Korean Intellectual Property Office on Apr. 29, 2021, the entire contents of which are hereby incorporated herein by reference.

### TECHNICAL FIELD

The present invention relates to a highly stretchable superhydrophobic thin film using initiated chemical vapor deposition and a method of preparing the same, and more particularly to a highly stretchable superhydrophobic thin film obtained by copolymerizing a fluorine monomer containing 4 to 6 fluoroalkyl groups with a small amount of a crosslinker using initiated chemical vapor deposition (iCVD), and a method of preparing the same.

### BACKGROUND ART

Hydrophobicity is a property of an object having no affinity for water, and is determined by measuring the contact angle with water on the surface of an object. The case in which the water contact angle exceeds 150° is referred to as superhydrophobicity. Superhydrophobic surfaces are applied across a wide range of fields such as those of electronic products, fabrics, building materials, and the like, and are utilized for antifouling coating and self-cleaning to remove contaminants.

In particular, recently, the need for a thin and uniform superhydrophobic film has arisen in order to miniaturize electronic devices and ensure the transparency of displays. Korean Patent No. 10-1644025 discloses the synthesis of a nano-scale superhydrophobic thin film using initiated chemical vapor deposition (iCVD). Since initiated chemical vapor deposition (iCVD) is a process of synthesizing a polymer through radical polymerization by introducing a monomer in a gas phase, it has the advantage of being able to apply monomers having various functional groups to various substrates and of copolymerizing monomers having diverse properties at a desired ratio. Moreover, since it is a dry process performed in a vapor phase, there is no contamination due to residue and there is no damage to the substrate. Furthermore, adsorption of the monomer is controlled by adjusting the temperature regardless of the chemical properties of the substrate, so polymer coating is possible on various substrates without surface pretreatment.

However, most superhydrophobic inorganic and organic coatings are brittle due to physical properties such as crystallinity of the coating itself and thus are easily broken when bent or stretched. Accordingly, it is difficult to attain durability in foldable and wearable devices, which has recently become an issue.

Jie Ju et al. and Xiaojing Su et al. disclose methods of forming a coating film, the surface of which is coated with a composite structure of a polymer with silver or silica nanoparticles through spin coating and spray coating, and of modifying the surface thereof to be stretchable and superhydrophobic due to the rough physical configuration of the structure as well as the chemical properties of the film. However, these methods commonly have problems in which the thickness of the structure film reaches tens to hundreds of μm during spin coating and spray coating, and also in which transparency of the film cannot be ensured due to the roughness of the surface. In addition, due to a concern in which the solvent used for spin coating and spray coating may damage the substrate, for substrates sensitive to moisture and solvents in electronic devices and the like, surface modification may become difficult.

Accordingly, the present inventors have made great efforts to overcome the problems with the nano-scale superhydrophobic thin film using initiated chemical vapor deposition (iCVD), and thus ascertained that, when a fluorine monomer containing 4 to 6 fluoroalkyl groups and having a glass transition temperature of 5° C. or less and a crosslinking monomer are allowed to react on a substrate in the presence of an initiator in an initiated chemical vapor deposition reactor and thus applied in the form of a copolymer at a nanometer thickness on the substrate, a highly stretchable superhydrophobic thin film may be synthesized, making it possible to ensure the durability of foldable and wearable devices, thus culminating in the present invention.

### PRIOR ART DOCUMENTS

### Patent Literature

Korean Patent No. 10-1644025

### Non-Patent Literature

Jie Ju et al., A highly stretchable and robust non-fluorinated superhydrophobic surface, J. Mater. Chem. A, 2017, 5, 16273-16280 Xiaojing Su et al., Highly Stretchable and Conductive Superhydrophobic
Coating for Flexible Electronics, ACS Appl. Mater. Interfaces 2018, 10, 10587-10597

### SUMMARY OF THE INVENTION

It is an object of the present invention to provide a highly stretchable superhydrophobic thin film having improved physical and chemical durability and transparency and a method of preparing the same.

In order to accomplish the above object, the present invention provides a method of preparing a superhydrophobic polymer thin film using initiated chemical vapor deposition (iCVD), comprising reacting a fluorine monomer containing 4 to 6 fluoroalkyl groups and having a glass transition temperature of 5° C. or less with a crosslinking monomer on a substrate in presence of an initiator in an iCVD reactor thereby forming a copolymer; and simultaneously coating the substrate with the copolymer formed.

In addition, the present invention provides a superhydrophobic polymer thin film, in which a substrate is coated with a copolymer of a fluorine monomer and a crosslinking monomer at a thickness of 5 nm to 500 μm and which has visible light transmittance of 93% or more.

### BRIEF DESCRIPTION OF THE DRAWINGS

The above and other objects, features, and other advantages of the present invention will be more clearly understood from the following detailed description taken in conjunction with the accompanying drawings, in which:

FIGS. 1A to 1C schematically show the principle by which a highly stretchable superhydrophobic polymer thin film according to the present invention is synthesized through iCVD and the surface properties thereof;

FIGS. 2A to 2C show the results of a stretch test performed on the highly stretchable superhydrophobic thin film according to the present invention; and

FIGS. 3A to 3C show the results of measurement of the physical and chemical durability and transparency of the highly stretchable superhydrophobic thin film according to the present invention.

### DETAILED DESCRIPTION OF THE INVENTION

Unless otherwise defined, all technical and scientific terms used herein have the same meanings as those typically understood by those skilled in the art to which the present invention belongs. In general, the nomenclature used herein and test methods described below are well known in the art and are typical.

With the goal of overcoming the disadvantage in which superhydrophobic inorganic and organic coatings are brittle due to physical properties such as crystallinity thereof and are easily broken when bent or stretched, the present invention is intended to confirm that, when a fluorine monomer containing 4 to 6 fluoroalkyl groups and having a glass transition temperature of 5° C. or less and a crosslinking monomer are allowed to react on a substrate in the presence of an initiator in an initiated chemical vapor deposition reactor and thus applied in the form of a copolymer at a nanometer thickness on the substrate, a highly stretchable superhydrophobic thin film may be synthesized, so the durability of foldable and wearable devices may be ensured.

An aspect of the present invention pertains to a method of preparing a superhydrophobic polymer thin film using initiated chemical vapor deposition (iCVD), comprising reacting a fluorine monomer containing 4 to 6 fluoroalkyl groups and having a glass transition temperature of 5° C. or less with a crosslinking monomer on a substrate in presence of an initiator in an iCVD reactor thereby forming a copolymer; and simultaneously coating the substrate with the copolymer formed.

Hereinafter, a detailed description will be given of the present invention.

The present invention makes it possible to synthesize a highly stretchable superhydrophobic thin film in which conventional problems are overcome using an initiated chemical vapor deposition (iCVD) process. This thin film may be synthesized through copolymerization by adding a small amount of a crosslinker to a fluorine monomer that contains 4 to 6 fluoroalkyl groups and has a low glass transition temperature (Tg) during initiated chemical vapor deposition (iCVD). Here, the reason for selecting a fluorine monomer containing 4 to 6 fluoroalkyl groups and having a low glass transition temperature (Tg) is that such a monomer has excellent superhydrophobic performance, and the reason for adding the crosslinker is that a fluorine monomer having a low glass transition temperature (Tg), which is unable to exist in the form of a polymer thin film at room temperature, is to be provided in the form of a polymer, namely an elastomer, through bonding with the crosslinker in a small amount. The glass transition temperature of the fluorine monomer may be 5° C. or less, preferably −100 to 5° C., and more preferably −60 to 5° C.

In the present invention, examples of the fluorine monomer that is used to synthesize a fluorine-based polymer through iCVD may include acrylates such as perfluorooctyl acrylate, perfluoroheptyl acrylate, and perfluorohexyl acrylate, methacrylates such as perfluorooctyl methacrylate, perfluoroheptyl methacrylate, and perfluorohexyl methacrylate, styrenes such as perfluorohexyl styrene, perfluoropentyl styrene, and perfluorobutyl styrene, and ethylenes or propylenes such as perfluorohexyl ethylene, perfluoropentyl ethylene, perfluorobutyl ethylene, 3-perfluorohexyl propylene, 3-perfluoropentyl propylene, and 3-perfluorobutyl propylene. Preferably, 2-(perfluorohexyl)ethyl acrylate or 2-(perfluorobutyl)ethyl acrylate is used.

In the present invention, the crosslinker that is the crosslinking monomer may have two or more vinyl groups, and may be at least one selected from the group consisting of 1,3,5-trivinyl-1,3,5-trimethyl cyclosiloxane, 1,3,5,7-tetravinyl-1,3,5,7-tetramethyl cyclotetrasiloxane, ethylene glycol dimethacrylate, ethylene glycol diacrylate, 1,4-butanediol diacrylate, 1,3-butanediol diacrylate, 1,4-cyclohexane dimethanol divinyl ether, di(ethylene glycol)divinyl ether, di(ethylene glycol diacrylate), neopentyl glycol diacrylate, 1,4-butanediol divinyl ether, methacrylic anhydride, triallyl phosphate, 2,4,6-trimethyl-2,4,6-trivinylcyclotrisilazane, glycerol dimethacrylate, hexavinyldisiloxane, and divinylbenzene, and preferably 1,3,5-trivinyl-1,3,5-trimethyl cyclosiloxane is used.

In the present invention, the molar ratio of the initiator to the fluorine monomer to the crosslinking monomer may be 1:0.1-25:0.1-25, and preferably 1:1-4:1-6.

The copolymer may be a random copolymer, a block copolymer, a graft copolymer, or a bilayer copolymer.

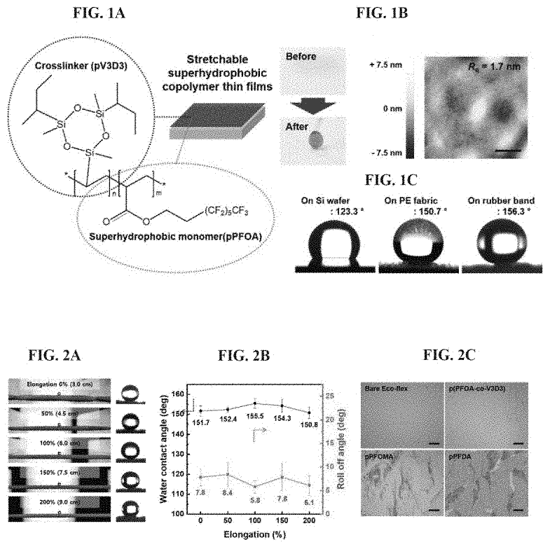

According to a preferred embodiment of the present invention, the fluorine monomer and the crosslinking monomer may be added at respective temperatures of 25 to 50° C. and 25 to 70° C. while the substrate is maintained at 10 to 50° C. Under reactor conditions of a filament temperature of 180° C. and an internal pressure of 50 to 500 Torr, a thin film may be obtained at a thickness of about 100 nm for 20 to 60 minutes. FIGS. 1A to 1C schematically show the principle by which the highly stretchable superhydrophobic polymer thin film according to the present invention is synthesized through iCVD. In FIGS. 1A to 1C, a highly stretchable superhydrophobic polymer thin film coated with a copolymer of Chemical Formula 1 is manufactured using PFOA as the fluorine monomer and V3D3 as the crosslinker.

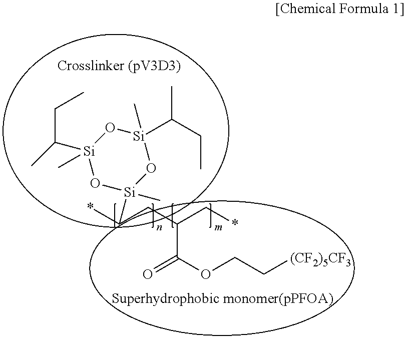

In Chemical Formula 1, the ratio of n and m is preferably in the range of 0.001:1 to 0.1:1.

According to an embodiment of the present invention, an acrylate-based fluorine polymer compound having 4 to 6 fluoroalkyl groups, preferably perfluorooctyl acrylate (PFOA) selected from among perfluorohexyl acrylate, perfluoroheptyl acrylate, and perfluorooctyl acrylate, and a crosslinker having two or more vinyl groups, preferably 1,3,5-trivinyl-1,3,5-trimethyl cyclosiloxane (V3D3), are copolymerized using initiated chemical vapor deposition (iCVD) to form a thin film (FIG. 1A). The surface roughness of a thin film deposited to a thickness of about 800 nm on the surface of a silicon wafer (Si wafer) was measured to be 1.7 nm or less using atomic force microscopy (AFM), indicating that the thin film was very uniformly deposited (FIG. 1B). Based on the results of measurement of the contact angle with water on a thin film deposited on a silicon wafer (Si wafer), polyester fabric, and flat rubber band, it was confirmed that the thin film was efficiently deposited on various substrates and that it was possible to impart superhydrophobicity of 150° or more thereto (FIG. 1C).

Also, in the present invention, the initiator may be at least one selected from the group consisting of peroxide compounds and benzophenone compounds of Chemical Formulas 2 to 6 below, preferably di-tert-butyl-peroxide (TBPO) of Chemical Formula 2, but is not limited thereto.

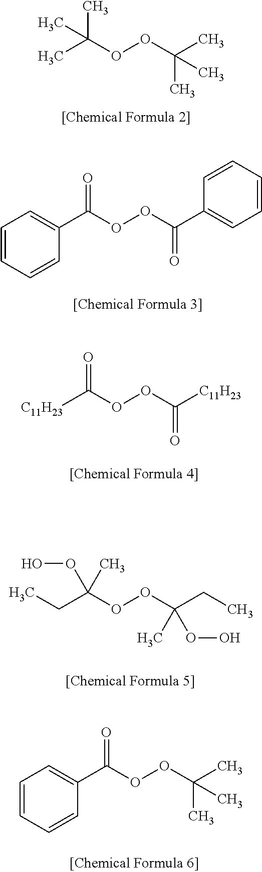

In the present invention, the substrate may be at least one selected from the group consisting of glass, a silicon wafer, polyethylene terephthalate (PET), polyimide, polyethylene-naphthalate (PEN), cellulose paper, nylon, polyester, polyacrylonitrile, polydimethylsiloxane, polyethersulfone (PES), polysulfone (PSF), poly(vinylidene difluoride) (PVDF), and stainless steel, and preferably a silicon wafer or the like, but is not limited thereto.

Since the process of the present invention uses neither a solvent nor an additive, a highly pure thin film may be obtained. In addition, the process is a low-temperature and low-vacuum-pressure process in which the surface temperature of the substrate is maintained as low as 45° C. or less, and enables vapor deposition, making it possible to deposit a thin film on various kinds of substrate, without limitation as to the kind of substrate. This solves conventional problems such as substrate damage caused by solvents, contamination caused by reaction residue, and selective coating depending on the characteristics of the substrate, which are inevitable in existing liquid-phase processes such as dip coating and spin coating. In particular, although the use of a liquid-phase process to synthesize a copolymer may cause problems of phase separation due to differences in physical and chemical properties between monomers, the process of the present invention is a gas-phase process, so copolymerization without phase separation between monomers is possible. The monomers used for the process are readily commercially available ones, rather than being separately synthesized therefor.

In general, when the surface of a substrate is modified through a liquid-phase process, limitations are imposed on the selection of the substrate due to the absorbency of the substrate. Moreover, the solvent used in the liquid-phase process may remain on the substrate and may thus act as a contaminant, or damage to the material surface may occur due thereto, and an additional post-treatment process may be required to remove the solvent. In the process of the present invention, a polymer thin film is grown on the surface of a material through surface modification using a vapor-phase process, whereby uniform surface modification is possible. Furthermore, since it is a dry process performed at a low temperature, it is possible to fundamentally prevent damage to the material caused by the solvent and reaction temperature.

The highly stretchable superhydrophobic thin film according to the present invention is capable of realizing a superhydrophobic surface of 150° or more by modifying the surface of a stretchable substrate and fabric, and exhibits elastomer performance capable of withstanding up to 200% elongation. In addition, it has been confirmed that it has high transparency of 93% or more in the visible light range, and is also very uniform, having a surface roughness of 1.7 nm or less.

Accordingly, another aspect of the present invention pertains to a superhydrophobic polymer thin film, in which a substrate is coated with a copolymer of a fluorine monomer and a crosslinking monomer at a thickness of 5 nm to 500 μm and which has visible light transmittance of 93% or more.

Moreover, it has been confirmed that the thin film according to the present invention has superior physical durability by maintaining superhydrophobicity of 150° or more without cracks in the surface thereof, upon a 200% elongation test repeated for 2000 cycles or more, and also that superhydrophobicity of 150° or more is maintained without chemical damage to the thin film in the results of impregnation tests with various organic solvents such as acetone and toluene for 24 hours or more. Therefore, the superhydrophobic polymer thin film according to the present invention may be stretched to 50% or more.

The thin film of the present invention, having high elastomer properties, superhydrophobicity, superior transparency, a very thin and uniform thin-film form, and superior physical and chemical durability, is expected to be widely utilized for antifouling coating and self-cleaning of electronic devices and functional fabrics requiring high stretchability.

A better understanding of the present invention may be obtained through the following examples. These examples are merely set forth to illustrate the present invention, and are not to be construed as limiting the scope of the present invention, as will be apparent to those skilled in the art.

### Example 1: Preparation of Highly Stretchable Superhydrophobic Polymer Thin Film: Preparation of p(PFOA-Co-V3D3)

As shown in FIGS. 1A to 1C, perfluorooctyl acrylate (PFOA, Aldrich) and 1,3,5-trivinyl-1,3,5-trimethyl cyclosiloxane (V3D3, Aldrich) monomers were placed in a monomer chamber in an iCVD reactor (Daegi Hightech) and heated to 35° C. and 60° C., respectively. TBPO (tert-butyl peroxide, Aldrich) was placed in an initiator chamber and maintained at room temperature.

A silicon wafer (Si wafer) was placed in the iCVD reactor, followed by copolymerization through iCVD for about 20 to 60 minutes under conditions of a filament temperature in the reactor of 180° C. and a chamber pressure in the reactor of 200 mTorr while maintaining the wafer at 38° C., thus synthesizing a p(PFOA-co-V3D3) (poly((perfluorooctyl acrylate)-co-1,3,5-trivinyl-1,3,5-trimethyl cyclotrisiloxane)) polymer thin film.

The surface roughness of the thin film deposited to a thickness of about 800 nm on the surface of the silicon wafer (Si wafer) was measured to be 1.7 nm or less using atomic force microscopy (AFM), indicating that the thin film was very uniformly deposited (FIG. 1B).

Based on the results of measurement of the contact angle with water on the thin film deposited on a silicon wafer (Si wafer), polyester fabric, and flat rubber band, it was confirmed that the thin film was efficiently deposited on various substrates and that it was possible to impart superhydrophobicity of 150° or more thereto (FIG. 1C).

### Example 2: Measurement of Stretchability of Highly Stretchable Superhydrophobic Thin Film

The stretchability of the polymer thin film synthesized in Example 1 was measured.

The thin film was deposited on a flat rubber band having a length of about 3 cm, after which a change in superhydrophobic performance of the surface was observed by measuring the water contact angle while applying an elongation of 0 to 200%. Thereby, it can be confirmed that the superhydrophobicity of the thin film was maintained even with an elongation of 200% (FIG. 2A). It can be confirmed that, in a graph of the change in contact angle measured in the above experiment, a water contact angle of 150° or more and a roll-off angle of 10° or less were maintained, even upon elongation of up to 200% (FIG. 2B). FIG. 2C shows results of comparison of the surface state after the stretch test with the existing polymer thin film. For p(PFOA-co-V3D3) prepared in Example 1, no cracks formed in the surface of the thin film after the 200% elongation test.

In contrast, it was confirmed that acrylate and methacrylate, having high crystallinity or high glass transition temperature (Tg), were vulnerable to stretching. In particular, poly(perfluorooctyl methacrylate) (pPFOMA) contains six fluoroalkyl groups, like PFOA (perfluorooctyl acrylate), but the glass transition temperature (Tg) thereof is about 40° C. higher, so cracks formed in the thin film during the stretch test. Also, poly(perfluorodecyl acrylate) has crystallinity due to 8 fluoroalkyl groups therein, so cracks formed in the thin film during the stretch test.

### Example 3: Measurement of Physical and Chemical Durability and Transparency of Highly Stretchable Superhydrophobic Thin Film

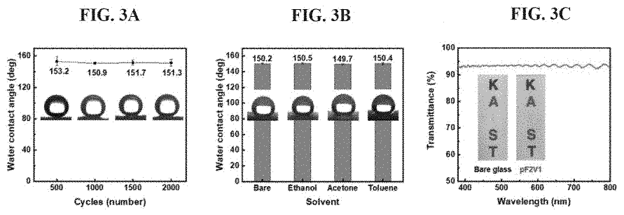

The physical and chemical durability and transparency of the highly stretchable superhydrophobic thin film synthesized in Example 1 were measured. As shown in FIG. 3A, the thin film was deposited to a thickness of about 400 nm on a flat rubber band, the stretch test was repeated for 2000 cycles with 200% elongation, and a change in the water contact angle was observed. Thereby, it was confirmed that superhydrophobicity was maintained even upon repeated stretch tests, indicating superior physical durability of the thin film. The thin film was deposited to a thickness of about 400 nm on a polyester fabric, the deposited fabric was immersed in ethanol, acetone, and toluene solvents for 24 hours, and a change in the water contact angle was observed (FIG. 3B). Thereby, it was confirmed that superhydrophobicity was maintained despite impregnation with organic solvents, indicating superior chemical durability of the thin film. As shown in FIG. 3C, the thin film was deposited to a thickness of about 3 μm on a slide glass, and the visible light transmittance thereof was measured to be about 93%, indicating high transparency of the thin film.

### INDUSTRIAL APPLICABILITY

As is apparent from the above description, a polymer thin film according to the present invention has not only high stretchability and superhydrophobicity but also excellent physical and chemical durability and transparency, so it is capable of ensuring durability when used for foldable and wearable devices.

Although specific embodiments of the present invention have been disclosed in detail above, it will be obvious to those skilled in the art that the description is merely of preferable exemplary embodiments and is not to be construed as limiting the scope of the present invention. Therefore, the substantial scope of the present invention will be defined by the appended claims and equivalents thereof.

1. A method of preparing a superhydrophobic polymer thin film using initiated chemical vapor deposition (iCVD), comprising reacting a fluorine monomer containing 4 to 6 fluoroalkyl groups and having a glass transition temperature of 5° C. or less with a crosslinking monomer on a substrate in presence of an initiator in an iCVD reactor thereby forming a copolymer; and simultaneously coating the substrate with the copolymer formed.

2. The method of preparing a superhydrophobic polymer thin film of claim 1, wherein the fluorine monomer is at least one selected from the group consisting of perfluorooctyl acrylate, perfluoroheptyl acrylate, perfluorohexyl acrylate, perfluorooctyl methacrylate, perfluoroheptyl methacrylate, perfluorohexyl methacrylate, perfluorohexyl styrene, perfluoropentyl styrene, perfluorobutyl styrene, perfluorohexyl ethylene, perfluoropentyl ethylene, perfluorobutyl ethylene, 3-perfluorohexyl propylene, 3-perfluoropentyl propylene, and 3-perfluorobutyl propylene.

3. The method of preparing a superhydrophobic polymer thin film of claim 1, wherein the crosslinking monomer has at least two vinyl groups.

4. The method of preparing a superhydrophobic polymer thin film of claim 3, wherein the crosslinking monomer is at least one selected from the group consisting of 1,3,5-trivinyl-1,3,5-trimethyl cyclosiloxane, 1,3,5,7-tetravinyl-1,3,5,7-tetramethyl cyclotetrasiloxane, ethylene glycol dimethacrylate, ethylene glycol diacrylate, 1,4-butanediol diacrylate, 1,3-butanediol diacrylate, 1,4-cyclohexane dimethanol divinyl ether, di(ethylene glycol)divinyl ether, di(ethylene glycol diacrylate), neopentyl glycol diacrylate, 1,4-butanediol divinyl ether, methacrylic anhydride, triallyl phosphate, 2,4,6-trimethyl-2,4,6-trivinylcyclotrisilazane, glycerol dimethacrylate, hexavinyldisiloxane, and divinylbenzene.

5. The method of preparing a superhydrophobic polymer thin film of claim 1, wherein a molar ratio of the initiator:the fluorine monomer:the crosslinking monomer is 1:0.1-25:0.1-25.

6. The method of preparing a superhydrophobic polymer thin film of claim 1, wherein the copolymer is a random copolymer, a block copolymer, a graft copolymer, or a bilayer copolymer.

7. The method of preparing a superhydrophobic polymer thin film of claim 1, wherein the fluorine monomer and the crosslinking monomer are added at respective temperatures of 25-50° C. and 25-70° C. while maintaining the substrate at 10-50° C.

8. The method of preparing a superhydrophobic polymer thin film of claim 7, wherein an internal pressure of the iCVD reactor is 50 to 500 Torr, and reaction is carried out for 20 to 60 minutes.

9. The method of preparing a superhydrophobic polymer thin film of claim 1, wherein the initiator is at least one selected from the group consisting of compounds represented by Chemical Formulas 2 to 6 below.

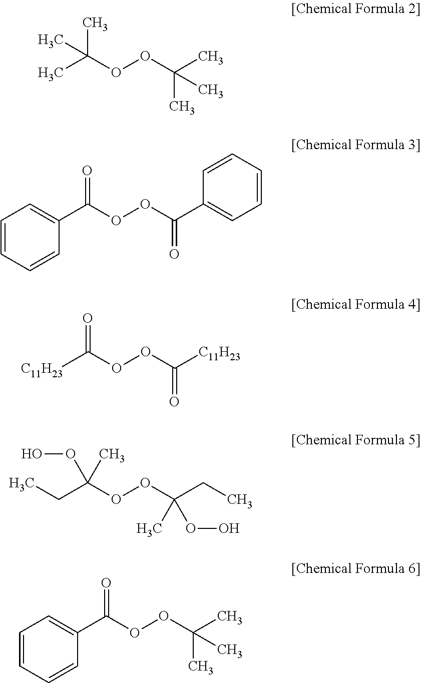

10. A superhydrophobic polymer thin film, in which a substrate is coated with a copolymer of a fluorine monomer and a crosslinking monomer at a thickness of 5 nm to 500 μm and which has a visible light transmittance of 93% or more.

11. The superhydrophobic polymer thin film of claim 10, wherein the fluorine monomer is at least one selected from the group consisting of perfluorooctyl acrylate, perfluoroheptyl acrylate, perfluorohexyl acrylate, perfluorooctyl methacrylate, perfluoroheptyl methacrylate, perfluorohexyl methacrylate, perfluorohexyl styrene, perfluoropentyl styrene, perfluorobutyl styrene, perfluorohexyl ethylene, perfluoropentyl ethylene, perfluorobutyl ethylene, 3-perfluorohexyl propylene, 3-perfluoropentyl propylene, and 3-perfluorobutyl propylene.

12. The superhydrophobic polymer thin film of claim 10, wherein the crosslinking monomer is at least one selected from the group consisting of 1,3,5-trivinyl-1,3,5-trimethyl cyclosiloxane, 1,3,5,7-tetravinyl-1,3,5,7-tetramethyl cyclotetrasiloxane, ethylene glycol dimethacrylate, ethylene glycol diacrylate, 1,4-butanediol diacrylate, 1,3-butanediol diacrylate, 1,4-cyclohexane dimethanol divinyl ether, di(ethylene glycol)divinyl ether, di(ethylene glycol diacrylate), neopentyl glycol diacrylate, 1,4-butanediol divinyl ether, methacrylic anhydride, triallyl phosphate, 2,4,6-trimethyl-2,4,6-trivinylcyclotrisilazane, glycerol dimethacrylate, hexavinyldisiloxane, and divinylbenzene.

13. The superhydrophobic polymer thin film of claim 10, wherein the copolymer is poly((perfluorooctyl acrylate)-co-1,3,5-trivinyl-1,3,5-trimethyl cyclosiloxane) (pPFOA-co-V3D3).
